(19) United States
(12) Patent Application Publication
(10) Pub. No.: US 2002/0007792 A1
(43) Pub. Date: Jan. 24, 2002

(54) Cathode electrode for plasma sources and plasma source of a vacuum coating device, in particular for the application of coating layers on optical substrates

(75) Inventor: Beat Siegrist, Herrliberg (CH)

Correspondence Address: THE FIRM OF KARL F ROSS, 5676 RIVERDALE AVENUE, PO BOX 900, RIVERDALE (BRONX), NY, 10471-0900, US

(73) Assignee: SATIS VACUUM INDUSTRIES VERTRIEBS-AG

(21) Appl. No.: 09/870,571

(22) Filed: May 31, 2001

(30) Foreign Application Priority Data
Jun. 8, 2000 (CH) 2000-1129/00

(51) Int. Cl. C23C 16/00

(52) U.S. Cl. 118/722

(57) ABSTRACT

The cathode electrode for plasma sources of a vacuum coating device, preferably for the application of coating layers on optical substrates, consists at least partially of a material with preferably as wide a band gap as possible of at least 3 eV between its energy bands. In this case, the wide band gap material of the cathode electrode doped for an optimal primary and secondary electron emission and can consist of diamond doped with nitrogen (N) or sulfur (S) or diamond with a codoping of boron (B) and nitrogen (N) or N-doped crystalline 6H—SiC and 4H—SiC (silicon carbide), or GaN, AlN and AlGaInN alloys doped with Zn, Si or Zn+Si, as well as BN, CN, BCN and other n-doped nitrides, borides and oxides.

As the band gap between two allowed bands increases, the emission of primary and secondary electrons rises significantly given a suitable energy supply.

### CROSS REFERENCE TO RELATED APPLICATION

This application claims the priority of Swiss Application No. 2000 1129/00 filed Jun. 8, 2000, which is incorporated herein by reference.

### FIELD OF THE INVENTION

This invention relates to a a cathode electrode for plasma sources of a vacuum coating device, in particular for the application of coatin layers on optical substrates.

### BACKGROUND OF THE INVENTION

Plasma sources for pre-cleaning the substrates and/or improving layer properties, e.g. compressing the layers to be evaporation coated or increasing adhesion, are known for the application of thin-layer systems an optical substrates, e.g., glasses, in a vacuum. A vacuum coating device of this kind is described in U.S. Pat. No. 4,817,559 of the same applicant, for example.

The disadvantage to this procedure is that only a moderate electrode emission can be achieved with conventional cathode electrodes. In addition, the emission of secondary electrons is minimal. The ion bombardment erodes the cathode, and the eroded material considerably contaminates the inside of the plasma source. The high level of cathode erosion also greatly diminishes the service life of the cathode and Plasma stability.

### SUMMARY OF THE INVENTION

The object of this invention is to effectively increase the quality of the cathode electrode for plasma sources.

According to the invention, this is first achieved by having the cathode electrode consist at least partially out of a material with preferably as wide a band gap as possible measuring at least 3 eV between its energy bands.

This is based an the theory in solid-state physics that the electron states are defined with the so-called band model in an crystalline solid, based upon which the electrons, especially those in the outer body areas, are combined into quasi-continuous (allowed) bands with a relatively high electrical conductivity, wherein the area between two allowed bands, here the retention zones for the electrons to be emitted, are designated as the disallowed band or disallowed energy range or band gap.

In this case, the wide band gap material of the cathode electrode is preferably doped for optimal primary and secondary electron emission.

In this connection, primary (electron) emission or primary electrons refer to the conventionally employed procedures for generating electron emissions from cathodes, e.g. via field emission (exiting of electrons from the cathode in response to an applied electrical field) or via thermionic mission (electron emission by heating the cathode, resulting in the exiting of thermionic electrons) or via thermal emission (electron emission from a heated cathode with simultaneously applied electrical field).

In addition, secondary (electron) emission or secondary electrons refer to the exiting of electrons from the cathode surface, as triggered by particle bombardment of the cathode; here via ion bombardment from the plasma.

It has now been found that, as the band gap between two allowed bands increases, the emission of primary and secondary electrons rises significantly given a suitable energy supply.

In another embodiment of this invention, doped diamond is another such material with elevated electron emission for the cathode; other materials include gallium nitride (GaN) or aluminum nitride (AlN), or aluminium-gallium-indium-nitride (AlGaInN) alloys. Such electrodes can be manufactured through gas phase separation (CVD process), sputtering or an epitaxial technique, for example. The electrodes can be heated directly via direct current or inductive high frequency, and indirectly via secondary resistance heating (thermal radiator). The electrons then emit thermoelectrically from the cathode with a low percentage of field emission. However, cathode action in field emission can be enhanced by applying a sufficiently high bias between the anode and cathode. As opposed to cathodes made out of metal oxide, ion bombardment here produces the desired elevated emission of secondary electrons.

In comparison with all other materials, the physical properties of diamonds are superior in all known areas of evaluations, as shown in the table below.

| Property | Value | Unit |
|---|---|---|
| Dielectric Constant | 5.61 | |
| Dielectric Strength | 1.0 × 10⁷ | V/cm |
| Dielectric loss | 6.0 × 10⁻⁴ | Tangent |
| Refractive Index | 2.4 | |
| Bandgap | 5.45 | eV |
| Hole mobility | 1.6 × 10³ | cm²/V-sec |
| Hole velocity | 1.0 × 10⁷ | cm/sec |
| Electron mobility | 2.2 X 10³ | cm²/V-sec |
| Electron velocy | 2.2 X 10⁷ | cm/sec |
| Resistivity | 1.0 × 10¹³ | ohm-cm |
| Thermal Conductivity | 2000 | W/m-K |
| Thermal Expansion Coefficient | 1.1 × 10⁻⁶ | /K |
| Work Function (111) face | −4.5 | eV |
| Lattice Constant | 3.57 | Angstroms |

The diamond material of the cathode has a very high emitting power for secondary electrons in comparison to conventional cathode materials. Diamond is highly chemically stable. This reduces the cathode erosion caused by ion bombardment, and hence the contamination of the plasma source. The low cathode erosion also effectively improves its service life, along with the stability of the plasma. Further, diamond has a high thermal conductivity, so that the heat generated by indirect or direct heating envelops the entire cathode fast and uniformly.

In a preferred embodiment, the cathode electrode can consist at least partially of doped diamond; and also doped GaN or doped AlN, or doped AlGaInN alloys.

In addition, the cathode electrode can have a metal substructure with an overcoat layer applied via gas phase separation (CVD process), sputtering or the epitaxial technique comprised of doped diamond; doped GaN or doped AlN, or doped AlGaInN alloys, wherein the metal substructure then preferably consists of tungsten (W) or molybdenum (Mo) or tantalum (Ta).

Further, this invention relates to a plasma source of a vacuum coating device for the application of coating layers on optical substrates, with a jacket-like anode electrode, an external magnetic coil, and a cathode electrode.

In this case, it is essential to the invention that the cathode electrode consists at least partially of a material with as wide a band gap as possible between its energy bands, wherein the wide band gap material of the cathode electrode is doped for an optimal primary and secondary electron emission.

The cathode electrode here consists at least partially of doped diamond or doped GaN or doped AlN or doped AlGaInN alloys. In addition, the cathode electrode can have a metal substructure with a protective coating applied via gas phase separation (CVD process), sputtering or an epitaxial technique comprised of doped diamond; doped GaN or doped AlN or doped AlGaInN alloys.

The metal substructure then preferably consists of tungsten (W) or molybdenum (Mo) or tantalum (Ta). In addition, the cathode electrode can have a cylindrical, conical, hood or dome-shaped or lattice-shaped design.

### BRIEF DESCRIPTION OF THE DRAWINGS

Examples for embodiments of the subject matter of the invention are explained in greater detail below based an the drawings. Shown on:

FIGS. 1a and 1b are two different embodiments of a plasma source for a vacuum coating device for the application of blooming coats on optical substrates;

FIGS. 2 to 5 are different embodiments of a cathode electrode for a plasma source according to FIG. 1, and

FIG. 6 is a homogenization device for the plasma source according to FIG. 1.

### DETAILED DESCRIPTION OF THE INVENTION

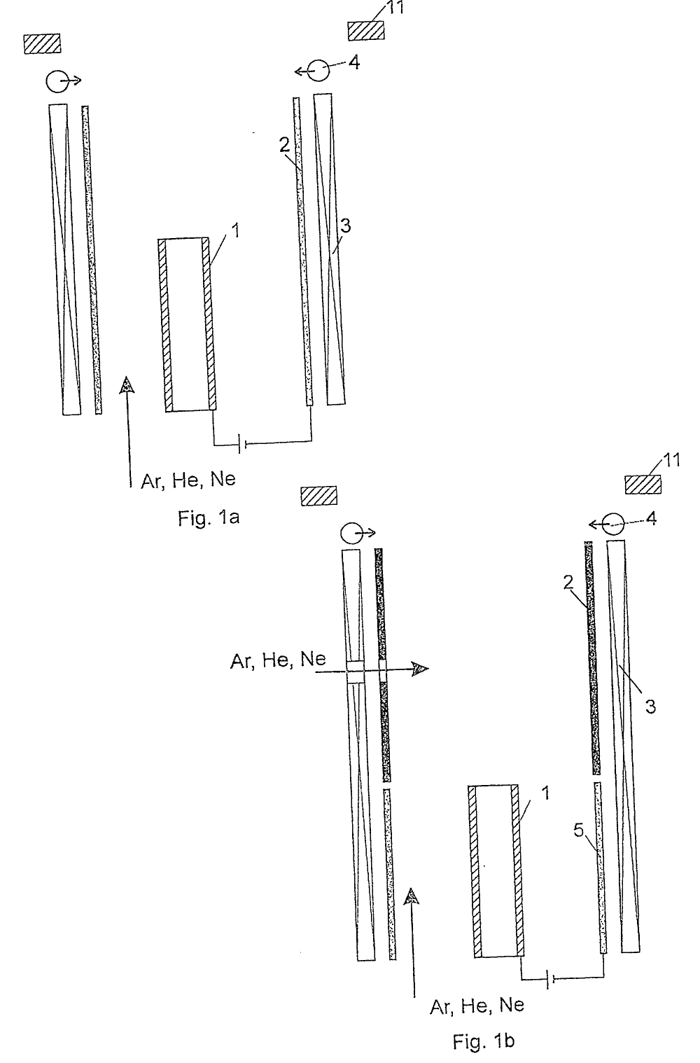

FIGS. 1a and 1b show two different embodiments of a plasma source for a vacuum coating device for the application of blooming coats an optical substrates, with a tubular or cylindrical anode 2 having a circular cross section, which envelopes an internal cathode 1, along with an external magnetic coil (solenoid) 3.

In FIG. 1a, the anode 2 directly envelops the cathode 1. By contrast, in FIG. 1b, the cathode 1 is enveloped by an insulation jacket made out of quartz or temperature-resistant ceramics 5, which abuts the anode z.

Such a plasma source is arranged in an evacuatable receiver (not shown). In this case, the cathode can be heated directly via direct current or inductive high frequency, or indirectly via secondary resistance heating (radiant heater). The electrons then emit from the cathode, as soon as it has reached a temperature at which the electrons overcome the energy difference of the cathode material bands.

The electron emission is primarily thermoelectric, with a small percentage being field electron emission. However, the cathode can also be effective in field emission by applying a high enough voltage between the anode and cathode, and a sufficiently low pressure in the vacuum chamber (good vacuum).

The discharge gas or gas mixture for generating the plasma in the receiver is an inert gas (working gas), such as argon (Ar), neon (Ne), helium (He), etc. In this case, the anode and cathode are connected with a voltage source to control the discharge voltage and current of the plasma.

The structural design of anode 2 on FIG. 1b is here modified in such a way as to reduce the direct impact of positively charged ions an cathode 1, resulting from the close proximity to the positively charged anode.

The magnetic coil 3 effectively acts an the electrons emitted by the cathode, and the ionized discharge gases, which flow upwardly and away from the cathode, carry the electrons along a spiral pattern of motion.

In addition, inlets 4 are provided above the anode 2 for a reactive gas, e.g. oxygen (O2) or nitrogen (N2), which reacts with the ionized inert gas (working gas) and high-energy electrons. This strong ion flow can be used for supporting and improving the quality (compact) the layers undergoing epitaxial growth during a vacuum coating process. In this case, a magnetic homogenization device 11 over the plasma outlet can increase the homogeneity of the plasma.

According to the Invention, the cathode electrode consists at least partially of doped materials with as wide a band gap as possible measuring at least 3 eV, with an especially widespread primary and secondary electron emission.

One such material with elevated electron emission for the cathode is doped diamond, for example. The diamond material of the cathode has a high-grade emitting power for secondary electrons relative to conventional cathode materials. This means that the cathode fall of the discharge is reduced, which decreases the overall power demand of the device. In addition, diamond is very chemically stable. This reduces the cathode erosion (material eroded as the result of ion bombardment) and hence the contamination of the plasma source, discharge space and receiver.

The low cathode erosion also effectively improves the service life of the cathode and stability of the plasma. Further, diamond has a high thermal conductivity, so that the heat generated via indirect or direct heating quickly and uniformly envelops the entire cathode.

The heat generated by ion bombardment is also relayed quickly through the entire cathode, which triggers a significantly elevated, uniform electron emission over the entire cathode surface.

As already mentioned, doped diamond doped with nitrogen (N) or sulfur (S) is a preferred material for the cathode electrode, wherein codoping with boron (B) and nitrogen (N) is also possible. Additionally possible are N-doped crystalline 6H—SiC and 4H—SiC (silicon carbide); GaN, AlN and AlGaInN alloys doped with Zn, Si or Zn+Si; along with BN, CN, BCN and other n-doped nitrides, borides and oxides.

In this case, the cathode can have a metal substructure with overcoat layer, for example applied via gas phase separation (CVD process), sputtering or an epitaxial technique, comprised of doped diamond, doped GaN or doped AlN or doped AlGaInN alloys, wherein the metal substructure preferably consists of tungsten (W) or molybdenum (Mo) or tantalum (Ta).

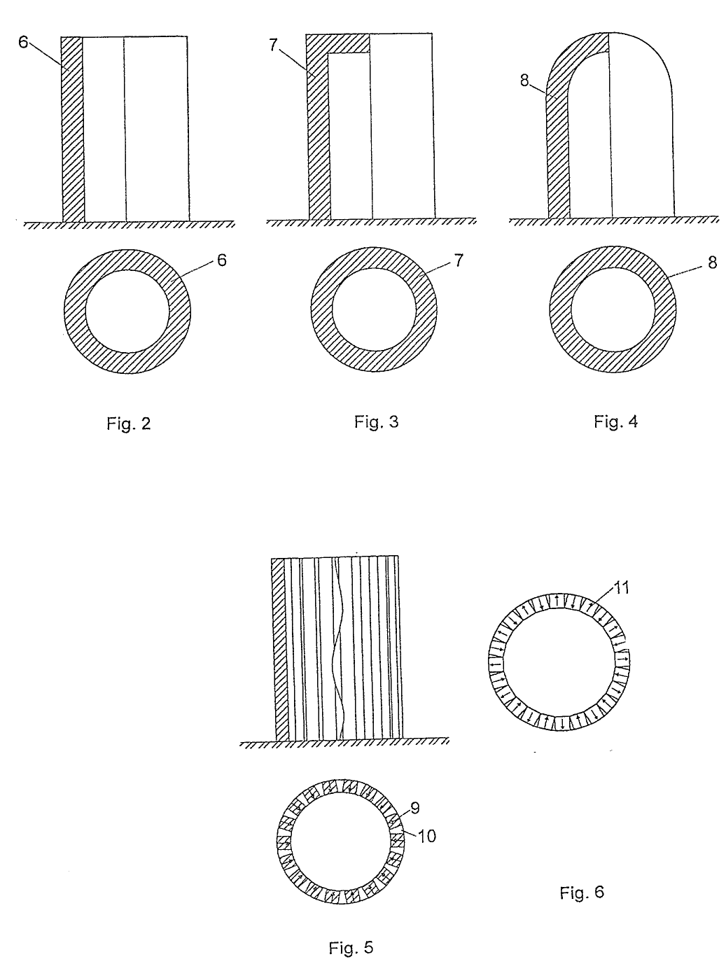

The cathode electrode can differ in configuration as well according to FIGS. 2 to 5, i.e. be a cylindrical body 6 according to FIG. 2, a pot-shaped body 7 according to FIG. 3, a dome-shaped body 8 according to FIG. 4, or a lattice 10 comprised of rods 9 according to FIG. 5. The cathode is here arranged coaxially to the anode (FIGS. 1a and 1b). As mentioned above, the cathode can here have a metal substructure, e.g., in the form of a frame made out of coiled wire, etc.

In addition, FIG. 6 shows a homogenization device 11 previously described on FIGS. 1a/1b in greater detail, which is located between the plasma source and substrates to be coated (not shown). In this case, a strong magnetic field is achieved by arranging magnets in a multiple pole reversal configuration that envelops the plasma beam. In this case, for example, an ion velocity of 1 m/s rotating clockwise to the magnetic field can be generated by means of SmCo magnets given a magnetic field with a strength of 410 mT and an electron temperature of 1 eV.

One such device can comprise 30 of the above SmCo magnets for a homogenization device measuring approx. 22 cm in diameter.

What is claimed is:

1. Cathode electrode for plasma sources of a vacuum coating device for the application of coating layers on optical substrates,
characterized in that
the cathode electrode consists at least partially of a material with as wide a band gap a possible of at least 3 eV between its energy bands.

2. Cathode electrode according to claim 1,
characterized in that
the wide band gap material of the cathode electrode is doped for an optimal primary and secondary electron emission.

3. Cathode electrode according to claim 2,
characterized in that
the wide band gap material of the cathode electrode consists at least partially of doped diamond, doped GaN or doped AlN, or of doped AlGaInN alloys.

4. Cathode electrode according to claim 3,
characterized in that
the wide band gap material for the cathode electrode is diamond doped with nitrogen (N) or sulfur (S); diamond with a codoping of boron (B) and nitrogen (N) or N-doped crystalline 6H—SiC and 4H—Sic (silicon carbide), or GaN, AlN and AlGaInN alloys, doped with Zn, Si or Zn+Si, as well as BN, CN, BCN and other n-doped nitrides, borides.and oxides.

5. Cathode electrode according to claim 4,
characterized in that
it has a metal substructure with an overcoat layer applied via gas phase separation (CVD process), sputtering or the epitaxial technique comprised of doped diamond; doped GaN or doped AlN, or doped AlGaInN alloys, etc.

6. Cathode electrode according to claim 5,
characterized in that
the metal substructure preferably consists of tungsten (W) or molybdenum (Mo) or tantalum (Ta).

7. Plasma source of a vacuum coating device, in particular for the application of coating layers on optical substrates, with a jacket-like anode electrode, an external magnetic coil, and a cathode electrode,
characterized in that
the cathode electrode consists at least partially of a material with as wide a band gap as possible between its energy bands, wherein the wide band gap material of the cathode electrode is doped for optimal primary and secondary electron emission.

8. Plasma source according to claim 7,
characterized in that
the cathode electrode consists at least partially of doped diamond, doped GaN or doped AlN, or of doped AlGaInN alloys, etc.

9. Plasma source according to claim 8,
characterized in that
the cathode electrode has a metal substructure with an overcoat layer applied via gas phase separation (CVD process), sputtering or the epitaxial technique comprised of doped diamond; doped GaN or doped AlN, or doped AlGaInN alloys, etc.

10. Plasma source according to claim 9,
characterized in that
the metal substructure preferably consists of tungsten (W) or molybdenum (Mo) or tantalum (Ta).

11. Plasma source according to claim 9,
characterized in that
the cathode electrode has a cylindrical, conical, pot-shaped, hood or dome-shaped or lattice-shaped design.
